(19) United States
(12) Patent Application Publication
(10) Pub. No.: US 2005/0151268 A1
(43) Pub. Date: Jul. 14, 2005

(54) Wafer-level assembly method for chip-size devices having flipped chips

(76) Inventors: William D. Boyd, Frisco, TX (US); Chris Haga, McKinney, TX (US); Anthony L. Coyle, Plano, TX (US); Leland S. Swanson, McKinney, TX (US); Quang X. Mai, Sugar Land, TX (US)

Correspondence Address: TEXAS INSTRUMENTS INCORPORATED, P O BOX 655474, M/S 3999, DALLAS, TX, 75265, US

(21) Appl. No.: 10/826,713

(22) Filed: Apr. 16, 2004

Related U.S. Application Data
(60) Provisional application No. 60/535,572, filed on Jan. 8, 2004.

(51) Int. Cl. H01L 21/48; H01L 29/40

(52) U.S. Cl. 257/778; 438/108; 257/781; 257/784; 438/617; 257/737; 438/613

(57) ABSTRACT

A method for assembling a whole semiconductor wafer (101) with a plurality of device units (120) having metal contact pads. Each contact pad has a patterned barrier metal layer and a metal stud (103, preferably copper or nickel) with an outer surface suitable to form metallurgical bonds without melting. A leadframe suitable for the whole wafer is provided, which has a plurality of segments groups (102), each group suitable for one device unit; each segment has first (102a) and second ends (102b) covered by solderable metal. A predetermined amount of solder paste (104) is placed on each of the first segment ends. The leadframe is then aligned with the wafer so that each of the paste-covered segment ends is aligned with the corresponding metal stud of the respective device unit. The leadframe is connected to the wafer and the whole wafer is encapsulated (105) so that the device units and the first segment ends are covered, while the second segment ends remain exposed. The encapsulated wafer is separated (110) into individual device units (120).

### FIELD OF THE INVENTION

The present invention is related in general to the field of electronic systems and semiconductor devices and more specifically to a wafer-level assembly method for chip-size, leadless devices having chips flip-assembled without bumps.

### DESCRIPTION OF THE RELATED ART

The fabrication of semiconductor devices is commonly based on assembly and packaging of individual semiconductor chips. One type of such assembly is the flip-chip technology, which uses either solder bumps (often referred to as solder balls) or gold bumps to attach the chip to a substrate, or to attach a package device to an external part.

There are several issues with the bumped flip-chip approach. First, the technology is expensive compared to conventional wire bonding assembly. The typical solder bumping process is very equipment intensive, resulting in a large capital cost. The application of pre-fabricated solder balls and the evaporation, plating, or screening of solder material are environmentally unfriendly in that they make use of excess of solder, often containing lead. Both processing and clean-up costs are high in these operations.

Second, the manufacturing of flip-chip assembly can have a long cycle time. Typically, reflows which are carried out in infrared or forced convection ovens have cycle times of 5 minutes or longer. These furnaces are usually very long (>3 m) and massive structures, occupying much space on the assembly floor. Moving parts in such furnaces are a significant source of particulate contamination.

Third, several metallurgical solder fillets contain brittle compounds and are thus at risk of bond failures. An example is tin-containing solder reacting with gold bumps. Generally, interconnections based on bumps are prone to fatigue and to develop microcracks, when exposed to thermo-mechanical stress in temperature cycle tests and device operation. As a remedy following the solder reflow step, flipped chips often use a polymeric underfill between the chip and the interposer or board to alleviate mechanical stress caused by the mismatch in the coefficients of thermal expansion (CTE) between the semiconductor chip, the interposer, if any, and the board. Some reliability problems occur due to the stress caused by the underfill process itself.

Another problem is caused by the ongoing trend to shrink the size of current packaging architectures. This shrinkage affects the board area consumed by the package, as well as the height needed by assembled devices. Obviously, tall interconnection bumps, which are favored for stress tolerance, are inimical to shrinking the height contour of assembled parts; further, removing the heat during device operation is aggravated by small package sizes and/or the lack of good heat conductors.

### SUMMARY OF THE INVENTION

A need thus exists for an assembly and packaging strategy to create a low-cost flip-chip technology, preferably without solder or gold bumps, resulting in devices of small area and height contours combined with good thermal dissipation capabilities. Preferably this strategy should be flexible enough to be applied to wafer-scale assembly, potentially in the clean room facilities of the wafer fab itself, and true chip-size packages.

One embodiment of the invention is a method for assembling a whole wafer with a plurality of device units having metal contact pads. Each contact pad has a patterned barrier metal layer and a metal stud (preferably copper or nickel) with an outer surface suitable to form metallurgical bonds without melting are on each pad. A leadframe suitable for the whole wafer is provided, which has a plurality of segments groups, each group suitable for one device unit; each segment has first and second ends covered by solderable metal. A predetermined amount of solder paste is placed on each of the first segment ends. The leadframe is then aligned with the wafer so that each of the paste-covered segment ends is aligned with the corresponding metal stud of the respective device unit. The leadframe is connected to the wafer and the whole wafer is encapsulated so that the device units and the first segment ends are covered, while the second segment ends remain exposed. The encapsulated wafer is separated into individual device units, resulting in a plurality of chip-size devices.

The method includes the assembly of extra-thin silicon wafers, a welcome contribution for fabricating low-height chip-size devices. Further, the method may comprise the attachment of a heat spreading metal sheet to the wafer surface opposite the active surface. This step is performed prior to the step of encapsulation.

Another embodiment of the invention is a method for assembling a semiconductor device by providing a chip, which has an active surface protected by an overcoat with a plurality of windows to expose the metal contact pads. On each pad are a patterned barrier layer and a metal stud with an outer surface suitable to form metallurgical bonds without melting. In addition, a leadframe with a plurality of segments is provided, each segment having first and second ends covered by solderable metal. A predetermined amount of solder paste is placed on each of the first segment ends; the leadframe is then aligned with the chip so that each of the paste-covered segment ends is aligned with the corresponding chip metal stud. The chip is then connected to the leadframe by contacting the metal studs and the first segment ends and reflowing the solder paste. Finally, chip and first segment ends are encapsulated by a molding compound, while leaving the second segment ends are left exposed.

Another embodiment of the invention is a semiconductor device comprising a semiconductor chip having an active surface protected by an overcoat, which has a plurality of windows exposing the metal contact pads. A patterned barrier layer is on the pad metal in the windows and on those portions of the overcoat, which surround the perimeter of the windows. The chip has a plurality of patterned metal studs, one stud each on a barrier layer and each stud having an outer surface suitable to form metallurgical bonds without melting. The device has further a plurality of leadframe segments, which have first and second ends. The first end of each segment is connected to one of the studs on the contact pads, respectively. Chip and leadframe segments are encapsulated by a molding compound except for the second end of each segment, which remains exposed.

The metal contact pads may comprise either aluminum, or copper, or an alloy thereof; the stud metal may comprise either copper or nickel. The segment-to-stud connection is provided by reflowable metal, which preferably comprises a mixture of flux and one or more of the metals tin, indium, bismuth, silver, and lead. The paste smoothes any uneven surface contour of the patterned stud.

It is a technical advantage of the present invention that a wide variety of materials and techniques can be employed for the proposed metallization and assembly steps.

Other technical advantages of the present invention include a reduction of manufacturing cost, a lead-free assembly solution, improved thermal performance of the package, and improved reliability of the device.

The technical advances represented by the invention, as well as the aspects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1 shows an embodiment of the invention; a schematic cross section illustrates a semiconductor wafer assembled on a leadframe by a flip-chip method without bumps, encapsulated, and awaiting singulation into chip-size devices.

FIG. 2 shows another embodiment of the invention; a schematic cross section illustrates a semiconductor wafer assembled on a leadframe by a flip-chip method without bumps, with a heat spreader attached, encapsulated, and awaiting singulation into chip-size devices.

FIG. 3 is a block diagram of the wafer assembly, packaging and singulation process flow according to the invention.

FIG. 4 is a block diagram of the device assembly and packaging process flow according to another embodiment of the invention.

FIG. 5A is a schematic cross section of an IC contact pad having under-bump metallization and a solder ball, flip-chip attached to a substrate, according to known technology.

FIG. 5B is a schematic cross section of an IC contact pad having a gold bump, flip-chip attached to a substrate, according to known technology.

FIG. 6 is a schematic cross section of an embodiment of the invention, showing a portion of a semiconductor device with a contact pad having an added metal stud with an outer layer surface suitable to form metallurgical bonds without melting, attached to a leadframe segment.

FIG. 7 is a schematic cross section of another embodiment of the invention, showing a semiconductor chip with contact pads having an added metal stud, solder-paste attached to a leadframe and encapsulated in a molding compound.

FIG. 8 is a schematic cross section of another embodiment of the invention, showing a semiconductor chip with contact pads having an added metal stud, solder-paste attached to a leadframe, the chip with a heat spreader attached, the unit encapsulated in a molding compound.

### DETAILED DESCRIPTION OF THE PREFERRED EMBODIMENTS

The present invention is related to U.S. patent Applications No. 10/001,302, filed on Oct. 01, 2001 (Zuniga-Ortiz et al., “Bumpless Wafer Scale Device and Board Assembly”); No. 10/057,138, filed on Jan. 25, 2002 (Zuniga-Ortiz et al., “Flip-Chip without Bumps and Polymer for Board Assembly”); No. 10/678,709, filed on Oct. 3, 2003 (Bojkov et al., “Sealing and Protecting Integrated Circuit Bonding Pads”); and No. 10/689,386, filed on Oct. 20, 2003 (Bojkov et al., “Direct Bumping on Integrated Circuit Contacts Enabled by Metal-to-Insulator Adhesion”).

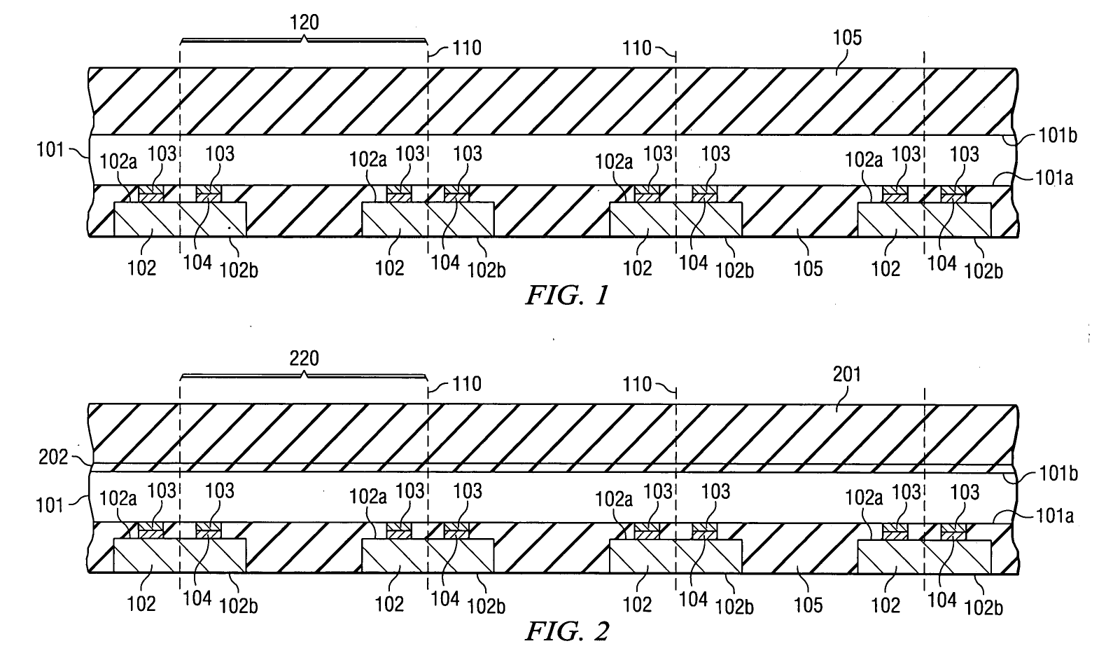

The schematic cross section of FIG. 1 shows an embodiment of the invention. A semiconductor wafer 101 with an active surface 101a is assembled on a leadframe, which has a plurality of leadframe segments 102. The assembly is performed by means of attaching the plurality of contact studs 103 (more detail below) of the active wafer surface with solder paste 104. An encapsulation material (preferably a molding compound) 105 covers the passive wafer surface 101b as well as the active wafer surface 101a including the contact studs 103 and the first ends 102a of the leadframe segments. The second ends 102b of the leadframe segments remain exposed.

The encapsulated wafer is separated into individual device units, thereby creating a plurality of assembled, packaged semiconductor devices. The preferred method for wafer separation is a sawing technique, which is indicated in FIG. 1 by the dashed lines 110 of the paths taken by the rotating saw. Other options include laser cutting or high-pressure jets. The final semiconductor devices, generally designated 120 in FIG. 1, have chip-size configurations, which is an advantage especially in products requiring components of small area and little space consumption.

The schematic cross section of FIG. 2 shows another embodiment of the invention. A semiconductor wafer 101 (parts analogous to FIG. 1 are marked by the same number) with an active surface 101a is assembled on a leadframe, which has a plurality of leadframe segments 102. The assembly is performed by means of attaching the plurality of contact studs 103 of the active wafer surface with solder paste 104. A metal sheet 201 is attached to the passive wafer surface 101b by attach material 202 (preferably silver-filled epoxy or polyimide). An encapsulation material (preferably a molding compound) 105 covers the active wafer surface 101a including the contact studs 103 and the first ends 102a of the leadframe segments. The second ends 102b of the leadframe segments remain exposed.

The encapsulated wafer is separated into individual device units, thereby creating a plurality of assembled, packaged semiconductor devices. The preferred method for wafer separation is a sawing technique, which is indicated in FIG. 2 by the dashed lines 110 of the paths taken by the rotating saw. Other options include laser cutting or high-pressure jets. The final semiconductor devices, generally designated 220 in FIG. 2, have chip-size configurations and favorable thermal characteristics, which is an advantage especially in products requiring components of small area, little space consumption and high power capabilities.

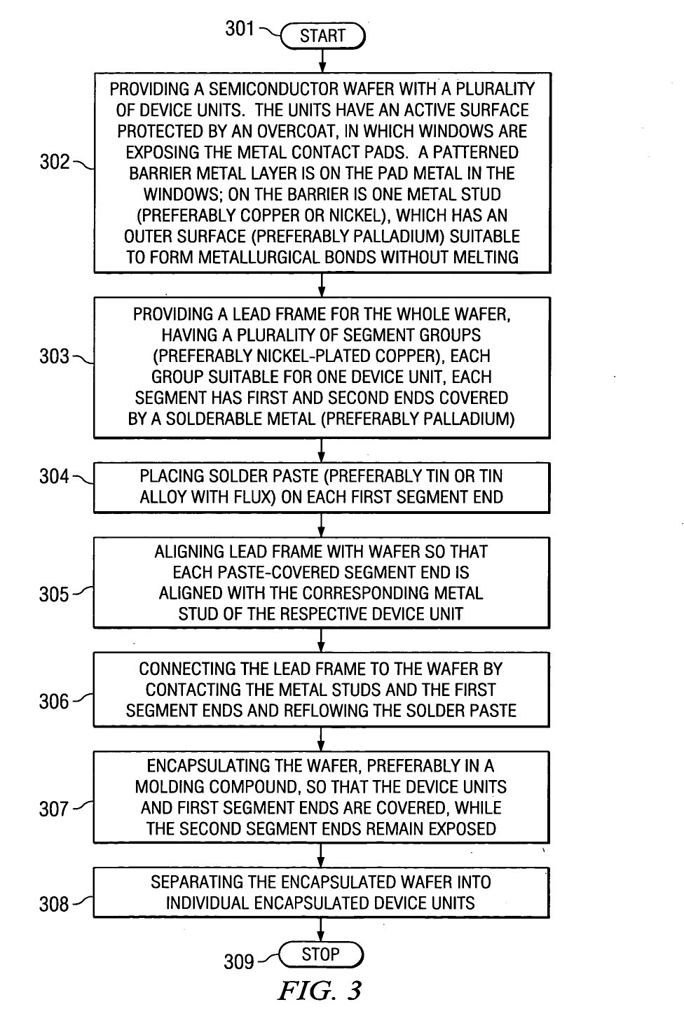

Another embodiment of the invention is a method for assembling semiconductor devices as depicted in the process flow block diagram of FIG. 3. After starting the assembly process at step 301, a whole semiconductor wafer with a plurality of device units is provided in step 302. These units have an active surface protected by an overcoat, in which windows are exposing the metal contact pads. A patterned barrier metal layer is on the pad metal in the windows and also on those portions of the overcoat, which surround the perimeter of the windows. On the barrier metal of each window is one metal stud, which has an outer surface suitable to form metallurgical bonds without melting. Preferred metals for the studs are copper and nickel.

In step 303 of this method, a leadframe is provided, which is suitable for the whole wafer. This leadframe has a plurality of segment groups, each group suitable for one of the device units; each segment has first and second ends covered by solderable metal. Preferred metal for the leadframe and the segments is nickel-plated copper.

In step 304 of the method, a predetermined amount of solder paste is placed on each of the first segment ends. Preferred pastes comprise flux and one or more of the metals tin, indium, bismuth, and silver (and lead, if necessary). The leadframe is then aligned in step 305 with the wafer so that each of the paste-covered segment ends is aligned with the corresponding metal stud of the respective device unit. The leadframe is connected in step 306 to the wafer by contacting the metal studs and the first segment ends and then reflowing the solder paste.

Next, in process step 307, the whole wafer is encapsulated, preferably in a molding compound, so that the device units and the first segment ends are covered, while the second segment ends remain exposed. Finally in step 308 of FIG. 3, the encapsulated wafer is separated into individual device units, thereby creating a plurality of assembled, packaged semiconductor devices. The preferred method for wafer separation is a sawing technique; other options include laser cutting or high-pressure jets. The method of FIG. 3 stops at step 309.

In an additional process step prior to step 307 of encapsulating, a metal sheet intended as a heat spreader is be attached to the wafer so that one sheet surface is adhered to the passive chip surface opposite the active surface, while the sheet surface opposite the adhered surface remains exposed. During the singulation step, the saw (or laser, etc.) cuts through the sheet, the wafer and the leadframe in the same process step. In the finished device, the spreader can act as heat radiator or is available for connection to an external heat sink.

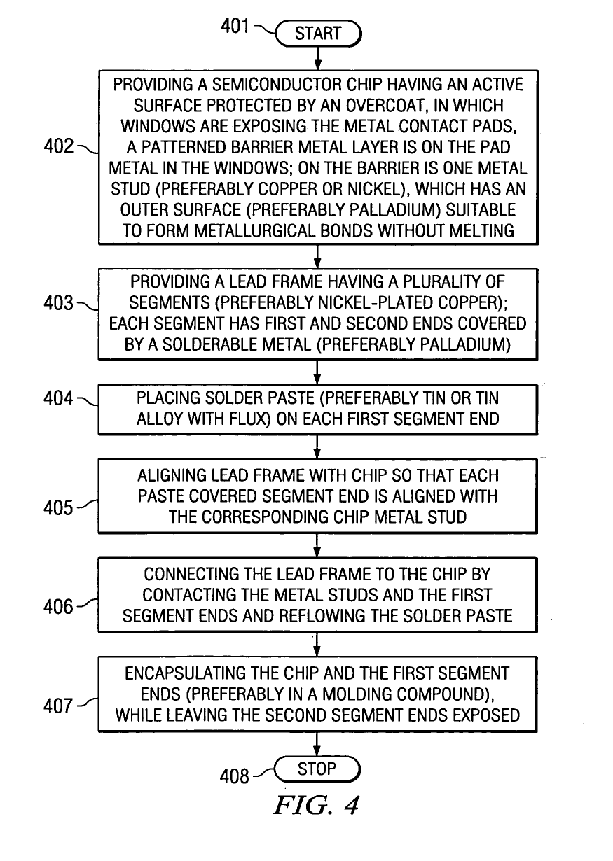

Another embodiment of the invention is a method for assembling a semiconductor device as depicted in the process flow block diagram of FIG. 4. After starting the assembly process at step 401, an individual semiconductor chip is provided in step 402. This chip has an active surface protected by an overcoat, in which windows are exposing the metal contact pads. A patterned barrier metal layer is on the pad metal in the windows and also on those portions of the overcoat, which surround the perimeter of the windows. On the barrier metal of each window is one metal stud, which has an outer surface suitable to form metallurgical bonds without melting. Preferred metals for the studs are copper and nickel.

In step 403 of this method, a leadframe is provided, which has a plurality of segments; each segment has first and second ends covered by solderable metal. Preferred metal for the segments is nickel-plated copper.

In step 404 of the method, a predetermined amount of solder paste is placed on each of the first segment ends. Preferred pastes comprise flux and one or more of the metals tin, indium, bismuth, and silver (and lead, if necessary). The leadframe is then aligned in step 405 with the chip so that each of said paste-covered segment ends is aligned with the corresponding chip metal stud. The leadframe is connected in step 406 to the chip by contacting the metal studs and the first segment ends and then reflowing the solder paste.

Finally, in step 407, the chip and the first segment ends are encapsulated, preferably by a molding compound, while leaving the second segment ends exposed. The method of FIG. 4 stops at step 408.

In an additional process step prior to step 407 of encapsulating, a heat spreader may be attached to the chip so that one heat spreader surface is adhered to the passive chip surface opposite the active surface, while the spreader surface opposite the adhered surface remains exposed. The spreader can thus act as heat radiator, or is available for connection to an external heat sink.

Another embodiment of the invention uses more than one chip in the process flow of FIG. 4, with the goal of assembling and packaging a multi-chip device. For this embodiment, a leadframe is provided, which is designed to hold the two or more chips in an assembly method employing flip-chip technique without bumps. The leadframe also provides the electrical interconnection between the chips.

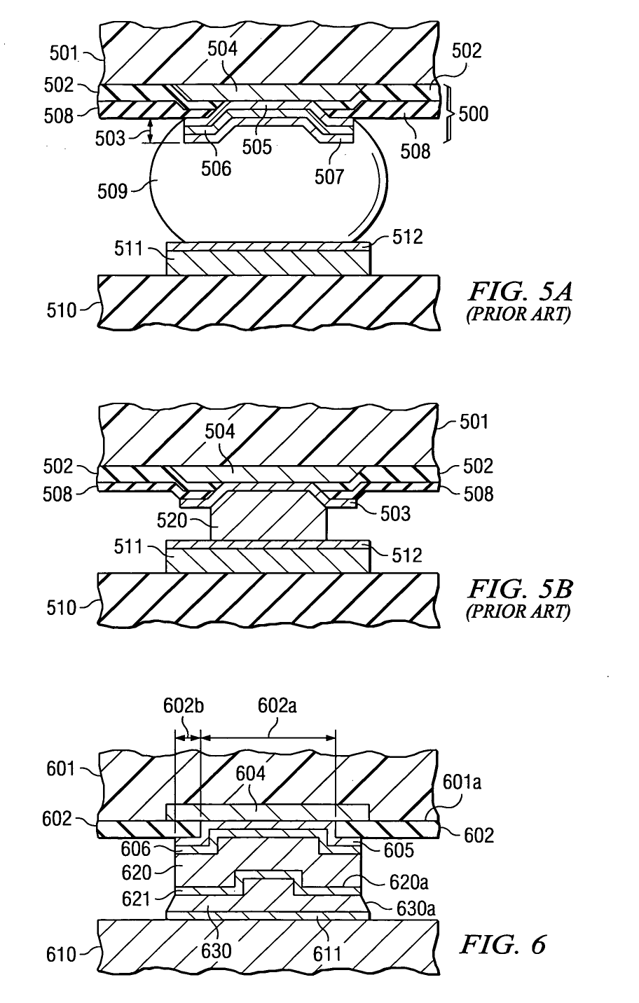

The bump-less assembly of the present invention can be most easily appreciated by highlighting the shortcomings of the known technology. As a typical example of the known technology, the schematic cross section of FIG. 5A illustrates the detail of the metallurgical requirements for the integrated circuit contact pad 500 in order to prepare it for flip-chip assembly using solder balls. An insulator portion 501 of the active surface of a semiconductor chip is protected by a practically moisture-impermeable dielectric protective overcoat 502, usually silicon nitride or silicon oxynitride. FIG. 5A also shows an optional additional organic overcoat 508. The circuit metallization 504 may be aluminum or an aluminum alloy, or it may be copper or a copper alloy.

A patterned “under-bump” metallization 503 over the aluminum or copper metallization 504 of the circuit contact pads consists of a sequence of several layers: When the circuit metallization 504 is aluminum, the conformal layer 505 adjacent to the circuit is typically a refractory metal 505, such as chromium, titanium, tungsten, molybdenum, tantalum, or alloys thereof. When the circuit metallization 504 is copper, the conformal layer 505 is typically aluminum, or copper on a carefully cleaned copper metallization. The following buffer layer 506 is typically nickel. The outermost layer 507 has to be a solderable metal, such as gold, copper, nickel, or palladium.

Finally, solder bump 509 is formed by reflowing the deposited (evaporated or plated) or attached solder alloy (typically a mixture of tin and lead, indium, or other metals). These solder bumps assume various shapes after attaching the chip to the substrate, influenced by the forces of surface tension during the reflow process.

The overall process to fabricate the contact pad depicted in FIG. 5A is expensive, since typically ten or more process steps are involved: Sputter chromium and copper (or nickel or any of a wide selection of metals described in the literature); spin resist; bake; expose; develop; etch metal; remove resist; seed solder; evaporate or plate solder; reflow solder; flip-chip attach.

In some process flows of the known technology, a layer 508 of polymeric material (benzocyclobutene, BCB) is deposited over the silicon nitride layer 502 so that it can act as a stress-relieving buffer between the under-bump metal 503 and the solder material 509. It has been shown to be useful in reducing solder joint failures when the solder bump has to withstand thermomechanical stresses in temperature variations.

The bumped chip is then flipped so that the active chip surface, including the integrated circuit, faces the substrate or assembly board 510, consisting in its bulk of insulating material. Substrate 510 has a metal contact pad 511, typically copper, which has a solderable surface 512, commonly a gold layer. Usually, some amount of solder paste is deposited on layer 512. Solder ball 509 is brought in contact with layer 512 and reflowed. After cool-down, the solder connection may have the contours depicted in the example of FIG. 5A; the contour shape depends on the amount of solder, the reflow time-temperature detail, and the strength of the surface tension.

The schematic cross section of FIG. 5B illustrates an analogous gold interconnection structure for a device assembled on a substrate. An insulator portion 501 of the active surface of a semiconductor chip is protected by a practically moisture-impermeable dielectric protective overcoat 502. The circuit metallization 504 may be aluminum or an aluminum alloy, or it may be copper or a copper alloy. The patterned under-bump metallization depicted as a single layer 503, frequently aluminum. The gold bump 520 connects to the top surface layer 512, preferably gold, of the pad metal 511, commonly copper, of substrate 510.

The process step of attaching gold bump 520 to the surface layer 512 of the substrate contact pad is usually performed with the aid of tin-containing solder paste in order to keep attachment time short and temperature low. The resulting fillet of the contact joint comprise gold/tin alloys which are mechanically brittle and thus put the reliability of the joint at risk.

The schematic cross section of FIG. 6 illustrates an embodiment of the invention, which eliminates the brittleness problem of the gold/tin fillet. FIG. 6 shows an insulating portion 601 of an integrated circuit or any other semiconductor device or component, which has an imbedded interconnecting metallization 604. The metallization is copper or a copper alloy in some devices; in other devices, it is made of aluminum or an aluminum alloy. The active surface 601a of insulator 601 has a protective overcoat 602, which preferably is made of practically moisture-impenetrable compounds such as one or more layers of silicon nitride, silicon oxynitride, or silicon carbide.

Overcoat 602 has a plurality of windows 602a, which expose the metallization 604. One or more conductive barrier layers 605 and 606 are on the metallization 604 exposed by the windows; these barrier layers are patterned so that they also cover the walls of the windows and a distance 602b of the insulator 602 surrounding the perimeter of the window. Preferred metals of the barrier layer are titanium/tungsten alloys; other choices include titanium, tungsten, tantalum, molybdenum, chromium, vanadium, alloys thereof, stacked layers thereof, and chemical compounds of these metals. The thickness of these one or more layers of metals is in the range from about 10 to 30 nm.

Attached to the outermost barrier layer of each window is a patterned metal stud 620. The preferred metal for stud 620 is copper or a copper alloy; alternatively, stud 620 is made of nickel or a nickel alloy. The preferred thickness range for stud 620 is between about 20 and 50 μm. Stud 620 has an outer surface 620a, which provides the ability to form metallurgical bonds without melting. This ability preferably is conveyed by a deposited metal film 621, which is preferably selected from a group consisting of a layer of nickel followed by an outermost layer of gold, and a layer of nickel followed by a layer of palladium and an outermost layer of gold. Other choices include silver or platinum. The thickness of film 621 is preferably less than 15 nm.

Further shown in FIG. 6 is a portion 610 of a leadframe segment. Typically, leadframes are made of a base metal, such as copper or a copper alloy (other choices include brass, aluminum, iron-nickel alloys, and invar), fully covered with a plated layer, such as nickel, cobalt, or alloys thereof (not shown in FIG. 6). As defined herein, the starting material of the leadframe is called the “base metal”, indicating the fundamental or starting metal. Consequently, the term “base metal” is not to be construed in an electrochemical sense (as in opposition to ‘noble metal’) or in a hierarchical sense.

Base metal has preferred thickness range from 100 to 300 μm; thinner sheets are possible. The plated layer is made of a bondable and solderable electronegative metal, covering the base metal and typically having a thickness between 0.2 and 1.0 μm. Preferred metals include nickel, cobalt and alloys thereof. Nickel in particular is favored because it reduces, when placed under tin or a tin-rich solder, the propensity for tin whiskers.

The leadframe segments are typically stamped or etched from a starting sheet of metal. Each segment has first and second ends; the first end serves the connection to the chip and the second end serves the connection to externals parts.

The metallurgical connection between chip contact stud 620 (with layer 621) and leadframe segment 610 is provided by reflowable metal 630, which is preferably a solder paste comprising a mixture of flux and one or more metals tin, indium, bismuth, and silver. During the reflow process, paste metals 630 may form meniscus 630a, and also smoothen any uneven surface contour, such as the step-like contour of the patterned stud 620 shown in FIG. 6. Furthermore, in order to facilitate the soldering process, the segment ends may exhibit additional outer metal layers. For the first segment end, the additional layer is designated 611 in FIG. 6, and is preferably made of thin (for example, 10 to 50 nm) silver or palladium. For the second segment end (not shown in FIG. 6), the additional layer is preferably thin (for example, 10 to 50 nm) palladium. As a further advantage, silver and palladium (also gold, platinum and rhodium) have an affinity to molding compounds and thus promote adhesion between molding compounds and those segment areas, which are covered by one or more of these metals and are exposed to molding compound.

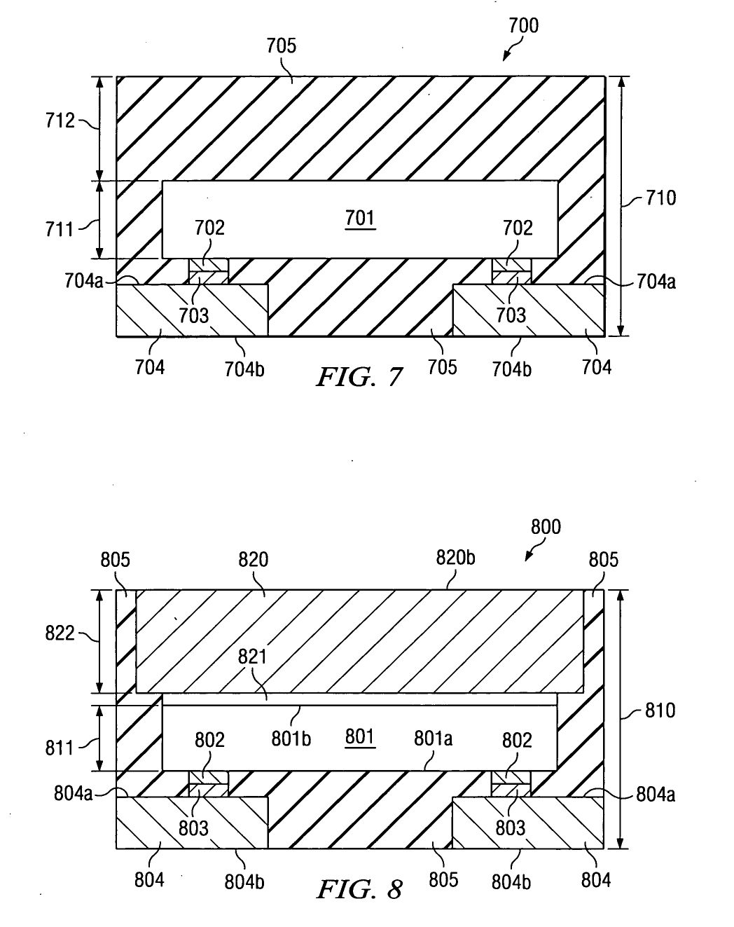

The schematic and simplified FIG. 7 shows the cross section of a discrete device, according to another embodiment of the invention and generally designated 700, encapsulated in molding compound. Semiconductor chip 701 has studs 702, made of copper or nickel, on its contact pads. Chip 701 is flipped and assembled with solder paste 703 on the first ends 704a of leadframe segments 704. Chip 701 and the first ends 704a of leadframe segments 704 are encapsulated, preferably by molding compound 705, so that the second ends 704b of segments 704 remain exposed. These exposed second ends 704b are thus available for the assembly of device 700 onto external parts (for instance by pressure contact, soldering technique, or otherwise).

As a result, device 700 is a leadless component flip-assembled without bumps (solder or gold). Due to the lack of bumps and protruding leads, the thickness 710 of device 700 can be made small. The preferred device thickness range is from 0.5 to 1.0 mm. Device thickness 710 can be reduced below 0.5 mm, when the chip thickness 711 is less than about 0.25 mm and the molding compound thickness 712 is less than about 0.20 mm.

As another embodiment of the invention, the schematic and simplified FIG. 8 shows the cross section of a device generally designated 800, which is encapsulated, preferably in molding compound, and also has a metallic heat spreader. Semiconductor chip 801 has studs 802, made of copper or nickel, on the contact pads on the active chip surface 801a. Chip 801 is flipped and assembled with solder paste 803 on the first ends 804a of leadframe segments 804. Chip 801 and the first ends 804a of leadframe segments 804 are encapsulated by material 805, preferably a molding compound, so that the second ends 804b of segments 804 remain exposed. These exposed second ends 804b are thus available for the assembly of device 800 onto external parts. Attached by adhesive film 821 (preferably a silver-filled epoxy or polyimide) to the passive chip surface 801b is metallic heat spreader 820. Preferably, heat spreader is made of copper or a heat-conducting copper alloy. The spreader surface 820b opposite the attached surface 820a is not covered by molding compound so that it can radiate heat freely or be connected to a heat sink, if desired.

As a result, device 800 is a leadless component, flip-assembled without bumps and distinguished by excellent thermal characteristics. Due to the lack of bumps and protruding leads, the thickness 810 of device 800 can be made small. The preferred device thickness range is from 0.5 to 1.0 mm. Device thickness 810 can be reduced below 0.5 mm, when chips with thickness 811 less than about 0.25 mm and heat spreaders with thickness 822 less than about 0.20 mm are used.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications and embodiments.

1. A method for wafer-level assembly of chip-size devices, comprising the steps of:
providing a semiconductor wafer having a plurality of device units, said units having contact pads covered by a solderable metallic member;
providing a wafer-level leadframe having a plurality of segment groups, each group suitable for one of said device units;
connecting said wafer to said leadframe;
encapsulating said assembled wafer and leadframe except for those segment portions intended for external connections; and
singulating said encapsulated assembly into discrete chip-size devices.

2. The method according to claim 1 wherein said metallic member is a copper stud.

3. The method according to claim 1 wherein said metallic member is a nickel stud.

4. The method according to claim 1 wherein said step of connecting is provided by means of solder paste.

5. A method for assembling semiconductor devices, comprising the steps of:
providing a semiconductor wafer having a plurality of device units, said units having an active surface protected by an overcoat, said overcoat having a plurality of windows exposing the metal contact pads, a patterned barrier metal layer on said pad metal in said windows and on portions of said overcoat, which surround the perimeter of said windows, a plurality of patterned metal studs, one stud each on a barrier layer, each stud having an outer surface suitable to form metallurgical bonds without melting;
providing a leadframe suitable for the whole wafer, said leadframe having a plurality of segment groups, each group suitable for one of said device units, each segment having first and second ends covered by solderable metal;
placing a predetermined amount of solder paste on each of said first segment ends;
aligning said leadframe with said wafer so that each of said paste-covered segment ends is aligned with the corresponding metal stud of the respective device unit;
connecting said leadframe to said wafer by contacting said metal studs and said first segment ends and reflowing said solder paste;
encapsulating said wafer in a molding compound so that said device units and said first segment ends are covered, while said second segment ends remain exposed; and
separating said encapsulated wafer into individual encapsulated device units to create a plurality of assembled, packaged semiconductor devices.

6. The method according to claim 5 wherein said step of separating said encapsulated wafer comprises a sawing technique.

7. The method according to claim 5 wherein said step of separating said encapsulated wafer comprises a laser cutting technique.

8. The method according to claim 5 wherein said device units are integrated circuits.

9. The method according to claim 5 wherein said assembled, packaged semiconductor devices are chip-scale devices.

10. The method according to claim 5 further comprising, prior to the step of encapsulating, the step of attaching a metal sheet to the wafer surface opposite to said active device surface so that the sheet surface opposite said attached surface remains exposed after said step of encapsulating.

11. A method for assembling a semiconductor device, comprising the steps of:
providing a semiconductor chip having an active surface protected by an overcoat, said overcoat having a plurality of windows exposing the metal contact pads, a patterned barrier metal layer on said pad metal in said windows and on portions of said overcoat, which surround the perimeter of said windows, a plurality of patterned metal studs, one stud each on a barrier layer, each stud having an outer surface suitable to form metallurgical bonds without melting;
providing a leadframe having a plurality of segments, each segment having first and second ends covered by solderable metal;
placing a predetermined amount of solder paste on each of said first segment ends;
aligning said leadframe with said chip so that each of said paste-covered segment ends is aligned with the corresponding chip metal stud;
connecting said chip to said leadframe by contacting said metal studs and said first segment ends and reflowing said solder paste; and
encapsulating said chip and said first segment ends by a molding compound, while leaving said second segment ends exposed.

12. The method according to claim 11 further comprising the step of attaching a heat spreader surface to the chip surface opposite said active surface prior to said step of encapsulating so that the spreader surface opposite said attached surface remains exposed.

13. A semiconductor device comprising:
a semiconductor chip having an active surface protected by an overcoat, said overcoat having a plurality of windows exposing the metal contact pads;
a patterned barrier layer on said pad metal in said windows and on portions of said overcoat, which surround the perimeter of said windows;
a plurality of patterned metal studs, one stud each on a barrier layer, each stud having an outer surface suitable to form metallurgical bonds without melting;
a plurality of leadframe segments, each segment having first and second ends, the first end of each segment connected to one of said studs on said contact pads, respectively; and
said chip and said leadframe segments encapsulated by a molding compound except for the second end of each segment, which remains exposed.

14. The device according to claim 13 wherein said metal contact pads comprise aluminum or an alloy thereof.

15. The device according to claim 13 wherein said metal contact pads comprise copper or an alloy thereof.

16. The device according to claim 13 wherein said barrier layer comprises a titanium/tungsten alloy.

17. The device according to claim 13 wherein said barrier layer is selected from a group consisting of titanium, tungsten, tantalum, molybdenum, chromium, vanadium, alloys thereof, stacks thereof, and chemical compounds thereof.

18. The device according to claim 13 wherein said barrier layer has a thickness range from about 10 to 30 nm.

19. The device according to claim 13 wherein said stud metal comprises copper or an alloy thereof.

20. The device according to claim 13 wherein said stud metal comprises nickel or an alloy thereof.

21. The device according to claim 13 wherein said stud has a thickness range from about 20 to 50 μm.

22. The device according to claim 13 wherein said outer surface of said stud metal provides its ability to form metallurgical bonds without melting by a deposited film, which is selected from a group consisting of a layer of nickel followed by an outermost layer of palladium, a layer of nickel followed by an outermost layer of gold, and a layer of nickel followed by a layer of palladium and an outermost layer of gold.

23. The device according to claim 22 wherein the thickness of said film is less than 15 nm.

24. The device according to claim 13 wherein said leadframe segments comprise a base of metal covered by a layer of solderable metal.

25. The device according to claim 24 wherein said base metal is copper in the thickness range from about 100 to 300 μm, and said solderable metal is nickel in the thickness range from about 0.2 to 1.0 μm.

26. The device according to claim 13 wherein said first segment ends have an outer region covered by a silver or palladium layer.

27. The device according to claim 13 wherein said second segment ends have an outer region covered by a palladium layer.

28. The device according to claim 13 wherein said overcoat comprises silicon nitride.

29. The device according to claim 13 wherein said overcoat is selected from a group consisting of silicon nitride, silicon oxynitride, silicon carbide, or a layered stack of said materials.

30. The device according to claim 13 wherein said segment-to-stud connection is provided by reflowable metal.

31. The device according to claim 30 wherein said reflowable metal is a solder paste comprising a mixture of flux and one or more of the metals tin, indium, bismuth, silver, and lead, said paste smoothing any uneven surface contour of said patterned stud.

32. The device according to claim 13 further comprising a heat spreader attached to the chip surface opposite said active surface.
